(19) United States
(12) Patent Application Publication
(10) Pub. No.: US 2002/0003484 A1
(43) Pub. Date: Jan. 10, 2002

(54) PLC device having variable resolution of temperature measurement

(76) Inventors: Seiji Oguro, Numazu-Shi (JP); Yoshiaki Shintani, Numazu-Shi (JP)

Correspondence Address: Pillsbury Winthrop LLP, East Tower, Ninth Floor, 1100 New York Avenue, N.W., Washington, DC, 20005-3918, US

(21) Appl. No.: 09/898,038

(22) Filed: Jul. 5, 2001

(30) Foreign Application Priority Data
Jul. 5, 2000 (JP) 2000-204065

(51) Int. Cl. H03M 1/18

(52) U.S. Cl. 341/139

(57) ABSTRACT

A PLC device of the invention includes an input part 11 that can be connected to a temperature sensor 30, which can output an voltage value depending on a temperature of an target object. A voltage amplifier 12 is connected to the input part 11. A switch 13 can be selectively connected to one of the input part 11 and the voltage amplifier 12 to be switched to one of a voltage value from the input part 11 and a voltage value from the voltage amplifier 12. An A-D converter 14 is connected to the switch 13 in such a manner that the one of the voltage value from the input part 11 and the voltage value from the voltage amplifier 12 is inputted to the A-D converter 14 and converted into a digital value by the A-D converter 14. A temperature obtaining part 15 is connected to the A-D converter 14 and can obtain a temperature of the target object from the converted digital value.

### BACKGROUND OF THE INVENTION

1. Field of the Invention

This invention relates to a PLC device that is connected to a temperature sensor, in particular to a PLC device that has a variable resolution of temperature measurement.

2. Description of the Related Art

A thermocouple sensor and a thermistor sensor are typical of temperature sensors for measuring a temperature of a target object.

The thermocouple sensor can measure the temperature very precisely. Thus, the thermocouple sensor is widely used as a sensor achieving a high-precision temperature control in a medical field, for example for an intensive care unit or the like. Alternatively, the thermocouple sensor is also widely used as a sensor achieving a high-precision temperature control in an industrial field, for example for a machine tool such as an injection molding unit.

The thermistor sensor has an advantage that it is cheaper than the thermocouple sensor, although it is inferior to the latter in measurement precision. Thus, the thermistor sensor is widely used as a temperature sensor in cases wherein a temperature control need not be conducted high precisely, for example for an electric rice-cooker, a vending machine and so on.

In other words, it is preferable that the thermocouple sensor is used in view of measurement precision, but it is preferable that the thermistor sensor is used in view of cost.

### SUMMARY OF THE INVENTION

The inventor has studied and studied how to achieve higher-precision temperature measurement by means of the cheaper thermistor sensor.

In general, among a variable temperature range of a target object, a temperature range whose temperature should be measured precisely is restricted narrowly. For example, in the case of an electric rice-cooker, the temperature range whose temperature should be measured precisely is about 80 to 150° C. Alternatively, in the case of an air conditioner, the temperature range whose temperature should be measured precisely is about 0 to 40° C. Alternatively, in the case of a refrigerator, the temperature range whose temperature should be measured precisely is around 10° C. Other parts of the respective variable temperature ranges need not to be measured so precisely.

Therefore, the object of this invention is to provide a PLC device having a variable resolution of temperature measurement for a part of a variable temperature range of a target object.

The invention is a PLC device comprising: an input part that can be connected to a temperature sensor that can output an voltage value depending on a temperature of an target object; an voltage amplifier connected to the input part; a switch that can be selectively connected to one of the input part and the voltage amplifier to be switched to one of a voltage value from the input part and a voltage value from the voltage amplifier; an A-D converter connected to the switch, the one of the voltage value from the input part and the voltage value from the voltage amplifier being inputted to the A-D converter and being converted into a digital value by the A-D converter; and a temperature obtaining part connected to the A-D converter, that can obtain a temperature of the target object from the converted digital value.

According to the invention, the temperature of the target object can be obtained (measured) with two resolutions that are by the voltage value from the input part and by the voltage value from the voltage amplifier.

It is very effective to improve measurement precision by using the voltage value from the voltage amplifier, especially if the temperature sensor has a thermistor whose resistance depends on the temperature of the target object.

Alternatively, this invention is a PLC device comprising: an input part that can be connected to a temperature sensor that can output an voltage value depending on a temperature of an target object; a first voltage amplifier connected to the input part; a second voltage amplifier connected to the input part; a switch that can be selectively connected to one of the first voltage amplifier and the second voltage amplifier to be switched to one of a voltage value from the first voltage amplifier and a voltage value from the second voltage amplifier; an A-D converter connected to the switch, the one of the voltage value from the first voltage amplifier and the voltage value from the second voltage amplifier being inputted to the A-D converter and being converted into a digital value by the A-D converter; and a temperature obtaining part connected to the A-D converter, that can obtain a temperature of the target object from the converted digital value.

According to the invention, the temperature of the target object can be obtained (measured) with two resolutions that are by the voltage value from the first voltage amplifier and by the voltage value from the second voltage amplifier.

### BRIEF DESCRIPTION OF THE DRAWINGS

FIG. 1 is a schematic block diagram of a PLC device according to an embodiment of the invention;

FIG. 2 is a graph showing a relationship between a temperature of the target object and an output of the temperature sensor; and

FIG. 3 is a graph showing a relationship between a temperature of the target object and an output of the voltage amplifier.

### BEST MODE FOR CARRYING OUT THE INVENTION

Embodiments of the invention are explained in more detail with reference to the drawings.

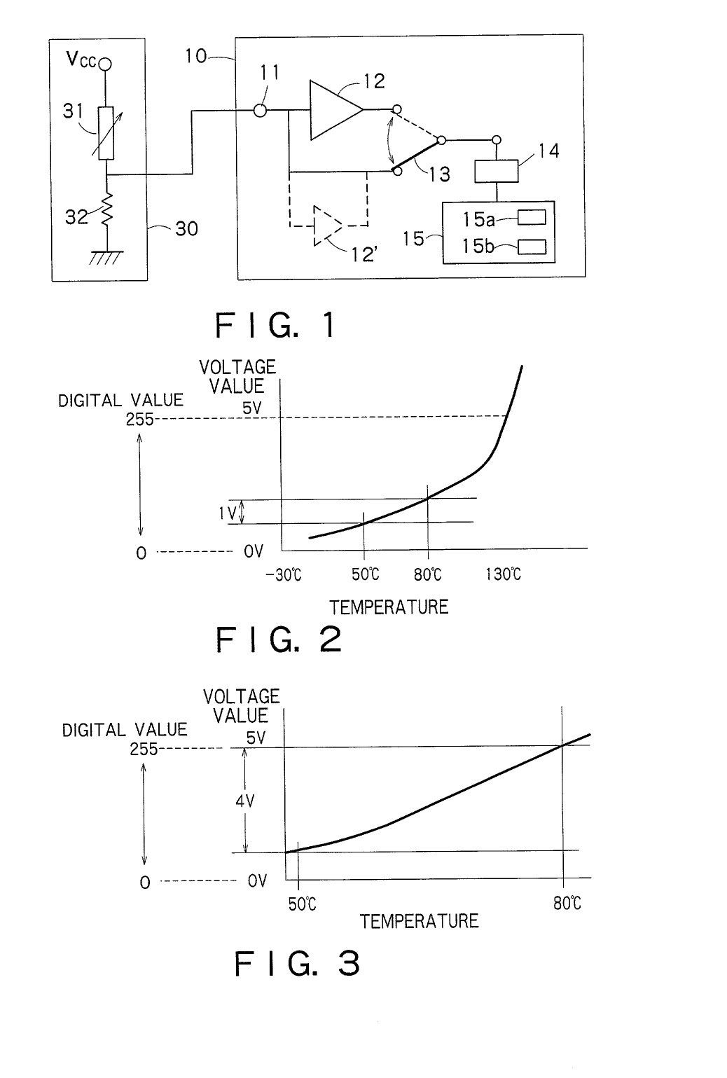

FIG. 1 is a schematic block diagram of a PLC device according to an embodiment of the invention. As shown in FIG. 1, the PLC (Programmable Logic Circuit) device 10 of the embodiment comprises an input part 11 that can be connected to a temperature sensor 30 that outputs an voltage value depending on a temperature of an target object.

In the case, the temperature sensor 30 is formed as a sensor that outputs a voltage value based on a ratio of a resistance of a thermistor 31 to a voltage-divider resistance 32. The resistance of the thermistor 31 depends on the temperature of the target object. There is a relationship as shown in FIG. 2 between the temperature of the target object and the output of the sensor (voltage value). That is, a temperature measurement range is about −30 to 130° C., which range corresponds to an output voltage range 0 to 5 V.

An voltage amplifier 12 is connected to the input part 11 of the PLC device 10. In the case, as shown in FIGS. 2 and 3, the voltage amplifier 12 is adapted to amplify (4 times) the output voltage value from the sensor 30 (the input voltage value of the input part 11) of a range of 1 to 2 V and adjust an offset of the amplified voltage value into a range of 1 to 5 V. The amplified voltage range corresponds to a temperature range of 50 to 80° C.

An switching end of a switch 13 can be selectively connected to one of the input part 11 and the voltage amplifier 12 in order to be switched to one of the voltage value from the input part 11 and the voltage value from the voltage amplifier 12. A common end of the switch 13 is connected to an A-D converter 14 into which the one of the voltage value from the input part 11 and the voltage value from the voltage amplifier 12 is inputted and by which the same is converted into a digital value.

In a normal state, the switch 13 is adapted to transfer the voltage value from the input part 11 to the A-D converter 14. Only when the voltage value from the input part 11 comes within the range of 1 to 2 V, the switch 13 is switched to transfer the voltage value from the voltage amplifier 12 to the A-D converter 14. In the case, the switch 13 is adapted to be automatically switched.

After that, if the voltage value from the input part 11 goes out from the range of 1 to 2 V, the switch 13 is switched back to transfer the voltage value from the input part 11 to the A-D converter 14. In the case, the switch 13 is adapted to be automatically switched back.

To the A-D converter 14, a temperature obtaining part 15 that can obtain a temperature of the target object from the converted digital value is connected.

The temperature obtaining part 15 has a first corresponding table 15a for obtaining the temperature of the target object from a digital value into which the voltage value from the input part 11 has been converted, and a second corresponding table 15b for obtaining the temperature of the target object from a digital value into which the voltage value from the voltage amplifier 12 has been converted. These tables 15a and 15b are made in advance based on various calibration experiments.

The temperature obtaining part 15 is adapted to use either of the first corresponding table 15a and the second corresponding table 15b, based on a state of the switch 13.

Then, an operation of the embodiment is explained as below.

In the embodiment, if the temperature of the target object changes, the resistance of the thermistor 31 also changes. Thus, the temperature sensor 30 outputs a voltage value based on the ratio of the resistance of the thermistor 31 to the voltage-divider resistance 32.

While the temperature of the target object is not within the temperature range of 50 to 80° C., the switch 13 is adapted to transfer the voltage value from the input part 11 to the A-D converter 14. Thus, the output value of the temperature sensor 30 is directly converted by the A-D converter 14, and then transferred to the temperature obtaining part 15.

The temperature obtaining part 15 is adapted to use the first corresponding table 15a in a state wherein the switch 13 is adapted to transfer the voltage value from the input part 11 to the A-D converter 14. Thus, the temperature obtaining part 15 can obtain a temperature of the target object from the digital value converted by the A-D converter 14, according to the first corresponding table 15a.

When the temperature of the target object comes within the temperature range of 50 to 80° C., the switch 13 is automatically switched to transfer the voltage value from the voltage amplifier 12 to the A-D converter 14. Thus, the value into which the output value of the temperature sensor 30 is amplified by the voltage amplifier 12 is converted by the A-D converter 14, and then transferred to the temperature obtaining part 15.

The temperature obtaining part 15 is adapted to use the second corresponding table 15b in a state wherein the switch 13 is adapted to transfer the voltage value from the voltage amplifier 12 to the A-D converter 14. Thus, the temperature obtaining part 15 can obtain a temperature of the target object from the digital value converted by the A-D converter 14, according to the second corresponding table 15b, more precisely (4 times on the average).

When the temperature of the target object goes out from the temperature range of 50 to 80 ° C. again, the switch 13 is automatically switched to transfer the voltage value from the input part 11 to the A-D converter 14. Thus, the output value of the temperature sensor 30 is converted by the A-D converter 14, and then transferred to the temperature obtaining part 15. Then, a temperature of the target object can be obtained, according to the first corresponding table 15a again.

As described above, according to the embodiment, the voltage value from the input part 11 and the voltage value from the voltage amplifier 12 are selectively converted by the A-D converter 14 so that the temperature of the target object can be obtained by means of two resolutions.

Especially, enhancement of the measurement precision while using the temperature sensor 30 formed by the cheaper thermistor is a very important advantage in cost.

In addition, in the embodiment, the switch 13 is automatically switched based on the voltage value from the input part 11. However, the switch 13 may be manually switched. Alternatively, the switch 13 may be controlled based on the temperature value obtained by the temperature obtaining part 15 or the like.

In addition, in the embodiment, the temperature of the target object is obtained from the digital value by using the first corresponding table 15a or the second corresponding table 15b. However, the temperature of the target object may be obtained from the digital value by using a formula through which a temperature value can be calculated from the digital value.

The temperature range for the higher-precision temperature measurement and the amplification can be freely changed. It is also possible to set a plurality of temperature ranges for the higher-precision temperature measurement. In addition, it is possible to achieve three resolutions of temperature measurement by further amplifying a part of the once amplified range. If a plurality of temperature ranges is set for the higher-precision temperature measurement, a plurality of offset-adjusting circuits and a plurality of corresponding tables may be necessary correspondingly to the respective temperature ranges. The plurality of temperature ranges set for the higher-precision temperature measurement may overlap with each other.

In addition, a second voltage amplifier 12′ may be arranged between the input part 11 and the switch 13. Then, the voltage value from the (first) voltage amplifier 12 and a voltage value from the second voltage amplifier 12′ are selectively converted by the A-D converter 14, so that two resolutions of temperature measurement can be achieved.

As described above, according to the invention, the temperature of the target object can be obtained (measured) by means of the two resolutions that are by the voltage value from the input part and by the voltage value from the voltage amplifier.

Alternatively, according to the invention, the temperature of the target object can be obtained (measured) by means of the two resolutions that are by the voltage value from the first voltage amplifier and by the voltage value from the second voltage amplifier.

What is claimed is:

1. A PLC device comprising;
an input part that can be connected to a temperature sensor that can output an voltage value depending on a temperature of an target object,
an voltage amplifier connected to the input part, a switch that can be selectively connected to one of the input part and the voltage amplifier to be switched to one of a voltage value from the input part and a voltage value from the voltage amplifier,
an A-D converter connected to the switch, the one of the voltage value from the input part and the voltage value from the voltage amplifier being inputted to the A-D converter and being converted into a digital value by the A-D converter, and
a temperature obtaining part connected to the A-D converter, that can obtain a temperature of the target object from the converted digital value.

2. A PLC device according to the claim 1, wherein:
the temperature sensor has a thermistor whose resistance depends on the temperature of the target object.

3. A PLC device according to the claim 2, wherein:
the temperature sensor is a sensor that can output a voltage value based on a ratio of a resistance of the thermistor to a voltage-divider resistance.

4. A PLC device according to the claim 1, wherein:
the switch is adapted to be automatically switched, based on the voltage value from the input part.

5. A PLC device according to the claim 1, wherein:
the switch is adapted to be manually switched.

6. A PLC device according to the claim 1, wherein:
the temperature obtaining part has:
a first corresponding table for obtaining the temperature of the target object from a digital value into which the voltage value from the input part has been converted, and
a second corresponding table for obtaining the temperature of the target object from a digital value into which the voltage value from the voltage amplifier has been converted.

7. A PLC device according to the claim 6, wherein:
the temperature obtaining part is adapted to use either of the first corresponding table and the second corresponding table, based on a state of the switch.

8. A PLC device comprising;
an input part that can be connected to a temperature sensor that can output an voltage value depending on a temperature of an target object,
a first voltage amplifier connected to the input part,
a second voltage amplifier connected to the input part,
a switch that can be selectively connected to one of the first voltage amplifier and the second voltage amplifier to be switched to one of a voltage value from the first voltage amplifier and a voltage value from the second voltage amplifier,
an A-D converter connected to the switch, the one of the voltage value from the first voltage amplifier and the voltage value from the second voltage amplifier being inputted to the A-D converter and being converted into a digital value by the A-D converter, and
a temperature obtaining part connected to the A-D converter, that can obtain a temperature of the target object from the converted digital value.

9. A PLC device according to the claim 8, wherein:
the temperature sensor has a thermistor whose resistance depends on the temperature of the target object.

10. A PLC device according to the claim 9, wherein:
the temperature sensor is a sensor that can output a voltage value based on a ratio of a resistance of the thermistor to a voltage-divider resistance.

11. A PLC device according to the claim 8, wherein:
the switch is adapted to be automatically switched, based on the voltage value from the input part.

12. A PLC device according to the claim 8, wherein:
the switch is adapted to be manually switched.

13. A PLC device according to the claim 8, wherein:
the temperature obtaining part has:
a first corresponding table for obtaining the temperature of the target object from a digital value into which the voltage value from the first voltage amplifier has been converted, and
a second corresponding table for obtaining the temperature of the target object from a digital value into which the voltage value from the second voltage amplifier has been converted.

14. A PLC device according to the claim 13, wherein:
the temperature obtaining part is adapted to use either of the first corresponding table and the second corresponding table, based on a state of the switch.
